(19) United States
(12) Patent Application Publication
(10) Pub. No.: US 2024/0250191 A1
(43) Pub. Date: Jul. 25, 2024

(54) THERMALLY INSULATIVE COMPOSITIONS FOR A SOLAR PANEL COATING

(71) Applicant: Nanotech Inc., Spring, TX (US)

(72) Inventors: Claudinei Calado Rezende, Spring, TX (US); Hani Taan, Spring, TX (US)

(73) Assignee: Nanotech Inc., Spring, TX (US)

(21) Appl. No.: 18/158,901

(22) Filed: Jan. 24, 2023

(51) Int. Cl. H01L 31/0216; C09D 7/61; H01L 31/048

(52) U.S. Cl. CPC H01L 31/02168; C09D 7/61; H01L 31/0481

(57) ABSTRACT

Compositions of matter for coating a solar panel are provided to increase the solar panel's efficiency. The solar panel coating may be applied to the outermost transparent layer of the solar panel that is exposed to the ambient environment, or in some instances, may be integrated with the outermost transparent layer. The solar panel coating allows enough light to pass through and reach the solar cells while also reducing heat transfer to the solar panel, thereby slowing the rate at which the solar panel heats up. The solar panel coating reduces heat transfer and promotes cooling of the solar panel at least in part by increasing emissivity of the solar panel's surface. The solar panel coating therefore elevates the solar panel's performance while adding minimal thickness to the solar panel.

### TECHNICAL FIELD

The present application relates generally to compositions of matter. More specifically, the present application provides compositions of matter for coating a solar panel.

### BACKGROUND

Thermal insulation materials have the ability to delay and/or hinder the propagation of thermal energy between two or more bodies. Conventional thermal insulation materials include rock wool, glass wool, and synthetic thermal insulation materials such as aerogels (e.g., silica aerogels), thermal inks and paints, and intumescent paints. There remains room to improve upon the properties provided by these conventional thermal insulation materials.

### SUMMARY

The present disclosure provides new and innovative compositions of matter for coating a solar panel to increase the solar panel's efficiency. The solar panel coating may be applied to the outermost transparent layer (e.g., glass) of the solar panel that is exposed to the ambient environment, or in some instances, may be integrated with the outermost transparent layer. Solar panels lose their efficiency when they get too hot. An advantage of the provided solar panel coating is that the solar panel coating allows enough light to pass through and reach the solar cells while also reducing heat transfer to the solar panel, thereby slowing the rate at which the solar panel heats up. For instance, the solar panel coating allows over 90% transmission for light in the 380 to 850 nm wavelength range. The solar panel coating reduces heat transfer and promotes cooling of the solar panel at least in part by increasing emissivity of the solar panel's surface. The solar panel coating therefore elevates the solar panel's performance. In various embodiments, the solar panel coating can provide the solar panel coating's advantageous insulative properties (e.g., low thermal conductivity) when applied, to the exposed transparent layer of the solar panel, with minimal thickness.

In an example, a solar panel includes at least one solar cell; a transparent layer disposed between the at least one solar cell and the ambient environment of the solar panel; and a composition of matter applied to the transparent layer. The composition of matter includes, by mass: 1 to 10% insulating compound, and a remaining portion resin. The insulating compound includes, by mass: 2 to 60% insulative particles, 5 to 40% micro silica, and 15 to 50% amorphous silica.

In various aspects, the resin is one in the group consisting of: silicone, urethane, acrylic, and polyethylene terephthalate (PET).

In various aspects, the composition of matter further includes, by mass, greater than 0% and less than or equal to 10% additives.

In various aspects, the composition of matter has an emissivity within a range of 0.80 to 0.86.

In various aspects, the composition of matter allows transmission of light through the composition of matter in the 380 to 850 nm wavelength range.

In various aspects, the composition of matter has a thickness within a range of 80 to 100 microns.

In various aspects, the insulating compound further includes one or more in the group consisting of: electro-fused silica, hydrated silica, inorganic fibers, bentonite, semiconductors, inert pigments, carbides, additives, resin, and water.

In various aspects, the insulating compound further includes, by mass, 5 to 50% electro-fused silica.

In various aspects, the insulating compound further includes, by mass, 20 to 40% hydrated silicate.

In various aspects, the insulating compound further includes, by mass, 5 to 40% inorganic fibers.

In various aspects, the insulating compound further includes, by mass, 1 to 5% bentonite.

In various aspects, the insulating compound further includes, by mass, 5 to 50% semiconductors.

In various aspects, the insulating compound further includes, by mass: 10 to 30% insulative particles, 5 to 10% micro silica, 25 to 50% amorphous silica, and 20 to 40% water.

In a second example, a solar panel includes at least one solar cell; a transparent layer disposed between the at least one solar cell and the ambient environment of the solar panel; and a composition of matter integrated with the transparent layer. The composition of matter includes, by mass: 1 to 10% insulating compound, and a remaining portion resin. The insulating compound includes, by mass: 2 to 60% insulative particles, 5 to 40% micro silica, and 15 to 50% amorphous silica.

In various aspects, the insulating compound further includes, by mass, 1 to 10% inert pigments.

In various aspects, the insulating compound further includes, by mass, 5 to 35% carbides.

In various aspects, the insulating compound further includes, by mass, 5 to 60% resin.

In various aspects, the insulating compound further includes, by mass, 20 to 60% water.

In various aspects, the composition of matter of the second example has an emissivity within a range of 0.80 to 0.86.

In various aspects, the composition of matter of the second example allows transmission of light through the composition of matter in the 380 to 850 nm wavelength range.

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a graph showing the heating and cooling of an insulating compound coating over time when subjected to direct heat.

FIG. 2 is a graph showing the thermal efficiency of an insulating compound over time.

FIG. 3 illustrates an example beer fermentation tank coated with a insulative coating, according to an aspect of the present disclosure.

FIG. 4 illustrates a schematic of a structure having a firewall coated with an insulative fireproof coating, according to an aspect of the present disclosure.

FIG. 5 illustrates a building with an insulative roof coating applied to the building's roof, according to an aspect of the present disclosure.

FIG. 6 illustrates a bus with an insulative vehicle coating applied to the roof of the bus, according to an aspect of the present disclosure.

FIG. 7 illustrates an exploded view of a solar panel having an insulative solar panel coating, according to an aspect of the present disclosure.

FIG. 8 illustrates a furnace coated with an insulative ceramic coating, according to an aspect of the present disclosure.

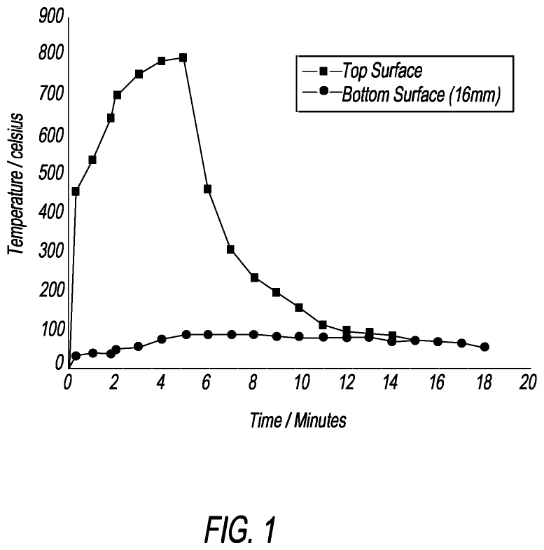

### DETAILED DESCRIPTION

The present application provides thermally insulative compositions of matter for use in a variety of applications that involve an underlying surface or structure that benefits from protection against external thermal energy. For example, a thermally insulative coating may be applied to a tank to insulate its contents. In another example, a fireproof coating may be applied to a firewall to prevent intrusion of life-threatening temperatures into a protected space. In another example, a coating may be applied to a building's roof or a vehicle's roof to reduce energy consumption when cooling the building's and vehicle's respective interiors. In a further example, a coating may be applied to a solar panel to increase photon conversion efficiency. In another example, an inorganic ceramic coating may be applied to a structure as a replacement for refractory materials.

### Insulating Compound

In the embodiments described below, the compositions of matter may include an insulating compound. The insulating compound works efficiently in the transfer of heat by each of conduction, convection, and radiation. Combining improvements in each of these three heat transfer attributes results in a more efficient thermally insulative material in some disclosed embodiments. Additional features in certain embodiments involving an insulating compound include flame retardance, thermal insulation, and anti-corrosion properties.

In various embodiments, the insulating compound includes at least insulative particles (e.g., 2% to 60%, 10 to 30%), micro silica (e.g., 5% to 40%, 5 to 10%), and amorphous silica (e.g., 15% to 50%, 25 to 50%). In some embodiments (e.g., the tenth example below), as an alternative to micro silica, the insulating compound includes at least insulative particles (e.g., 40 to 80%), hydrated silicate (e.g., 20 to 40%), and water (5 to 17%). In some embodiments, the insulating compound further includes suitable combinations of one or more of: electro-fused silica (e.g., 5 to 50%), inorganic fibers (e.g., 5 to 40%), bentonite (e.g., 1 to 5%), semiconductors (e.g., 2 to 30%), inert pigments (e.g., 1 to 10%), carbides (e.g., 5 to 35%), additives (e.g., 3 to 20%), resin (e.g., 5 to 60%), and water (e.g., 20 to 60%, 20 to 40%). In some examples, the insulating compound includes 10 to 30% insulative particles (e.g., nanoparticles), 5% to 10% micro silica, 25% to 50% amorphous silica, and 20 to 40% water, and in some instances may further include up to 10% inorganic fibers. Each of the example percentages is by mass.

In some embodiments, the micro silica is in the form of spheres. In embodiments that include hydrated silicate, the hydrated silicate may be, in some instances, thermally treated with aluminum and magnesium to form a fibrous aluminum silicate. In such instances, the fibrous aluminum silicate doesn't propagate flame spread and has a low thermal and electrical conductivity with a low density.

As used herein, insulative particles are defined as inorganic, thermally treated reagent particles that demonstrate insulative properties. In various embodiments, the insulative particles can react chemically with micro silica and amorphous silica to form a new phase denominated insulative compound. In some embodiments, the insulative particles can react chemically with hydrated silicate to form a new phase denominated insulative compound. In at least some aspects, the insulative particles may be nanoparticles. Including insulative nanoparticles in the insulating compound may provide the insulating compound with a porosity ranging from nano to mesopore when cured. This pore size distribution enables the insulating compound to reflect a range of wavelengths of radiation, such as ultraviolet to infrared length radiation. The wide range of reflectivity lowers the temperature of the composition of matter including the insulating compound under extreme heat conditions. The nanoparticles have a high surface area with a low thermal conductivity, and forms stable dispersions in aqueous solutions. The nanoparticles may be highly reactive based on the large surface area per mass of the nanoparticles. In various examples, the nanoparticles have a diameter within a range of 10 nm to 1000 nm, or in some instances within a range of 10 nm to 12 nm. The nanoparticles may be inorganic material that have high heat resistance, good mechanical resistance, and low electrical and thermal conductivity.

Including a semiconductor (e.g., an inorganic semiconductor) in the insulating compound can increase reflectivity of the compound's surface, reducing the surface temperature of the insulating compound when exposed to high temperatures. Example semiconductors include titanium oxide, magnesium oxide, chromite, aluminum-cobalt (CoAl), iron-chromium (FeCr), nickel-antimony-titanium (Ni—Sb—Ti), and carbides.

Dispersions of silica and/or amorphous silica in the insulating compound can provide strength, hardness, and resistance to high temperatures and thermal shock. Electro fused silica and/or bentonite may be used as thickeners and binders for the insulating compound.

Inorganic fibers provide the insulating compound with resistance to traction and flexion. Example inorganic fibers include glass, aramid, carbon, and mixed carbon and aramid. In some aspects the inorganic fibers may be functionalized and doped with graphene and nanotubes.

The inert pigments and/or additives are example rheological property modifiers. Example inert pigments include ferric oxides (e.g., greens, reds, yellows, carbon oxide, chromate 3 or 6 (different colors), calcium carbonate (white), etc.).

In some aspects, a resin (e.g., polymeric resin) may be used with the insulating compound as an agent of plasticity, tackiness and binder. In some instances, the resin may be water-based. In other instances, the resin is not water-based. Example resins include acrylic, alchemical, epoxy, polyurethane resins, phenol-formaldehyde, polyurethane, furfural resin, poly acrylonitrile, polyimide, sucrose and tannin.

In one example, the insulating compound is formed by dispersing insulative nanoparticles in a non-toxic reagent at a controlled pH using volatile bases with the aid of high-speed mechanical stirring in conjunction with ultrasonic mechanical stirring. Steps may be taken to promote the dispersion of the nanomaterials in the reagent which include pH control, viscosity and mechanical agitation at medium and high speed, and the use of a surfactant or ultrasonic waves.

The insulating compound may have a low thermal conductivity. For instance, the insulating compound may have a thermal conductivity within a range of 0.017 to 0.035 W/mK when exposed to a temperature of 1200° C. The insulating compound may also have a high reflectance and emissivity such that when radiated heat interacts with a surface of a layer of insulating compound, at least some of the heat is re-emitted, which reduces the surface temperature of the layer. For instance, the insulating compound can have an emissivity within a range of 0.90 to 1.0. In one example, the insulating compound may have an emissivity a range of 0.95 to 1.0. In another example, the insulating compound may have an emissivity of 1.0.

The insulating compound may have a low density. For instance, in at least some aspects, the density of the insulating compound in a dry state may be between 0.35 and 0.50 g·cm⁻³. The low weight of the insulating compound after curing may increase thermal insulation efficiency and minimize the weight added to the structure on which the insulating compound is applied. An additional feature in certain embodiments involving an insulating compound may be a negligible density of volatile organic compounds (VOC).

Embodiments combining high reflectance and emissivity with low density and low thermal conductivity may provide a very high cooling rate. For instance, t pl,′ is a graph showing the heating and cooling of a 16 mm thick sample coated with the insulating compound over time when subjected to a direct flame of 1200° C. The inventors found that the sample showed a surface temperature of 793° C. on the insulating compound coating and an opposite cold face side temperature of 79° C. after being exposed to a direct flame of 1200° C. After removing the sample from the heat, the surface temperature of the insulating compound coating fell to 57° C. in about 12 minutes.

The insulating compound may be thermally insulating over a broad range of high temperatures. For instance, the insulating compound can operate (e.g., demonstrates a thermal insulation effect) within a temperature range of 200 to 2100° C. Thermal conductivity of the insulating compound may increase as temperature increases. The insulating compound can operate within a temperature range of 500 to 2100° C., 750 to 2100° C., 1000 to 2100° C., 1200 to 2100° C., 1400 to 2100° C., 1700 to 2100° C., or another suitable range within 200 to 2100° C. The insulating compound may also be thermally insulating over a broad range of low temperature ranges. For instance, the insulating compound can operate within a temperature range of −200° C. to ambient temperature.

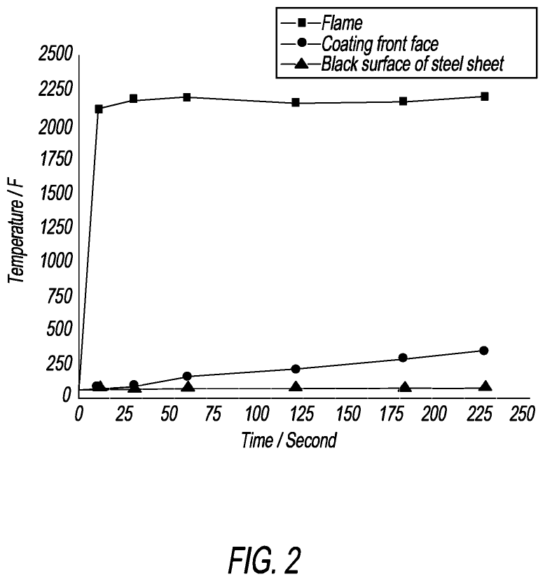

In a first example, an insulating compound includes, by mass: 2 to 60% insulative nanoparticles, 5 to 40% micro silica, 15 to 50% amorphous silica, 1 to 5% bentonite, and 5 to 50% water. In some instances of this first example, the insulating compound may further include, by mass: 1 to 10% inert pigments, 2 to 30% inorganic semiconductors, and 5 to 35% carbides. FIG. 2 is a graph showing the heating of the first example of the insulating compound incorporated into a polymer and coated on a steel sheet when the sample is exposed to direct flame. As shown in the graph, the fire exposure lasted about 3 minutes 45 seconds before it was terminated. The temperature on the front surface of the insulating compound coating layer gradually increased from 73.5° F. (23° C.) to about 342° F. (172° C.) while the flame temperature jumped to over 2000° F. (1100° C.) in about 11 seconds and maintained at that level for the duration of the test. The temperature on the back face of the steel sheet remained at between 72 to 73° F. (22° C. to 23° C.). The coating thickness estimated at the center of the fire exposure was in the range of 2 to 5 mm.

In a second example, an insulating compound includes, by mass: 10 to 60% insulative nanoparticles, 5% to 40% micro silica, 15% to 50% amorphous silica, 1 to 10% inert pigments, 3 to 20% additives, 2 to 20% inorganic semiconductors, 5 to 50% electro-fused silica, and 5 to 30% inorganic fibers.

In a third example, an insulating compound includes, by mass: 5 to 50% insulative nanoparticles, 5% to 40% micro silica, 15% to 50% amorphous silica, 1 to 10% inert pigments, 2 to 15% inorganic semiconductors, 5 to 35% electro-fused silica, 5 to 30% inorganic fibers, and 30 to 50% water.

In a fourth example, an insulating compound includes, by mass: 10 to 60% insulative nanoparticles, 5% to 40% micro silica, 15% to 50% amorphous silica, 1 to 10% inert pigments, 2 to 15% inorganic semiconductors, 5 to 35% electro-fused silica, 5 to 30% inorganic fibers, 2 to 4% bentonite, and 30 to 50% water.

In a fifth example, an insulating compound includes, by mass: 15 to 70% insulative nanoparticles, 5% to 40% micro silica, 1 to 8% inert pigments, 2 to 20% inorganic semiconductors, 5 to 30% electro-fused silica, 5 to 27% inorganic fibers, 5 to 20% amorphous silica, 1 to 5% bentonite, and 30 to 50% water.

In a sixth example, an insulating compound includes, by mass: 20 to 40% insulative nanoparticles, 5% to 40% micro silica, 2 to 23% inorganic semiconductors, 5 to 31% electro-fused silica, 5 to 21% inorganic fibers, 5 to 23% amorphous silica, 1 to 4% bentonite, and 20 to 60% water.

In a seventh example, an insulating compound includes, by mass: 30 to 80% insulative nanoparticles, 2 to 23% inorganic semiconductors, 5 to 33% micro silica spheres, 5 to 21% inorganic fibers, 5 to 23% amorphous silica, 1 to 4% bentonite, 5 to 15% carbides, and 20 to 60% water.

In an eighth example, an insulating compound includes, by mass: 10 to 50% insulative nanoparticles, 2 to 23% inorganic semiconductors, 5 to 33% micro silica spheres, 5 to 21% inorganic fibers, 5 to 23% amorphous silica, 1 to 4% bentonite, 5 to 30% electro-fused silica, 5 to 15% carbides, and 20 to 60% water.

In a ninth example, an insulating compound includes, by mass: 10 to 60% insulative nanoparticles, 5% to 40% micro silica, 15% to 50% amorphous silica, 1 to 10% inert pigments, 3 to 20% additives, and 2 to 20% inorganic semiconductors.

In a tenth example, an insulating compound includes, by mass: 15 to 40% hydrated silicate, 40 to 80% insulative particles (e.g., nanoparticles), and 5 to 17% water. In some aspects, the tenth example of the insulating compound may further include inorganic fibers (e.g., 5 to 20% by mass). In some aspects, the hydrated silicate is thermally treated with aluminum and magnesium to form a fibrous aluminum silicate. In various aspects of the tenth example, the insulating compound includes 15 to 40% magnesium silicate aluminum, 5 to 20% inorganic fibers, 40 to 60% insulative particles (e.g., nanoparticles), and 5 to 15% water. The tenth example of the insulating compound can be particularly useful for fireproofing and lowering the thermal conductivity of a material. The tenth example can also be used in various suitable carriers other than micro silica spheres, which can be beneficial because micro silica spheres can have less than desired mechanical properties. Stated differently, applying a material including the insulating compound in this tenth example to an object (e.g., a pipe) does not reduce the object's mechanical properties, in contrast to at least some typical insulation materials that use micro silica spheres. Example suitable carriers include water-based resins, solvent-based resins, thermoplastics, thermosets, epoxy, orthophthalic, cementitious materials, and silicones.

In some aspects, the insulating compound may be applied directly onto the surface of a suitable object. In other aspects, the insulating compound may be crushed and used as an insulating filler in other materials. For instance, the insulating compound may be isolated or dispersed in polymeric matrices (e.g., a resin), composites, metal alloys, inorganic materials (e.g., plaster, concrete, mortar, etc.), or other suitable materials to increase the resistance to thermal and electrical flow of those materials. The insulating compound can lower the thermal conductivity of a variety of materials. For example, the insulating compound may be included in each of the compositions of matter described below. In some aspects, a composition of matter described herein may be applied as a conventional paint using a spray system, airless, manual, projection equipment, or the like to form a uniform finishing layer of protective coating.

### General Insulative Coating Embodiment

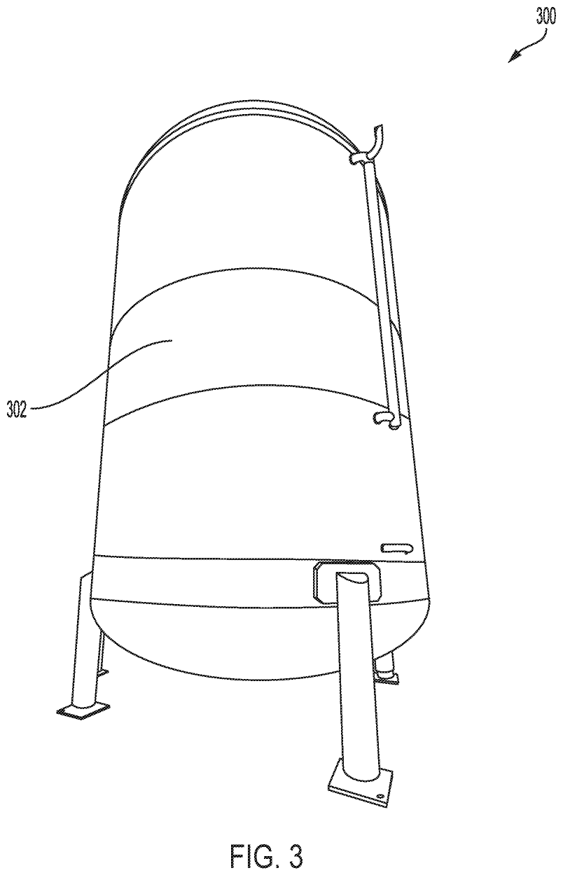

A first example application of the insulating compound is in an insulative coating. The insulative coating can be applied to any suitable structure for which insulation is beneficial. For example, the insulative coating may be applied to the interior and/or exterior of a beer fermentation tank in order to reduce the use of glycol on a jacked system. FIG. 3 illustrates an example beer fermentation tank 300 with an insulative coating 302 applied to an exterior of the body of the beer fermentation tank 300. The insulative coating 302 may be any embodiment of the insulative coating described herein. In another example, the insulative coating may be applied to the interior and/or exterior of a water boiler in order to reduce the number of boiler strikes by keeping heat inside portable structures and keeping cold out. An advantage of the insulative coating is the minimal thickness it adds to the structures on which it is applied while still providing equivalent or better insulative properties as other, thicker insulating materials.

The provided insulative coating has a low thermal conductivity and high emissivity which contribute to the insulative coating's desirable insulative properties. For instance, an embodiment of the insulative coating may have a thermal conductivity within a range of 0.017 to 0.035 W/mK (e.g., when exposed to a temperature of 1200° C.). In various embodiments, the insulative coating may have an emissivity within a range of 0.95 to 1.0. In some aspects, the insulative coating may have an emissivity of 0.97. In at least some aspects, the insulative coating may operate (e.g., demonstrates a thermal insulation effect) within a temperature range of −32 to 150° C. (−25 to 302° F.). For example, the insulative coating has a thermal conductivity within a range of 0.017 to 0.035 W/mK when the insulative coating is exposed to a temperature range of −32 to 150° C. (−25 to 302° F.). In various embodiments, the insulative coating can provide the insulative coating's insulative properties when applied, to a surface, with a thickness within a range of 1 to 20 millimeters (mm). In some embodiments, the insulative coating may be applied with a thickness within a range of 3 to 7 mm and demonstrate the described insulative properties.

In various examples, the insulative coating may include a combination of: a resin (e.g., 40 to 70%, 45 to 60%), micro silica (e.g., 5 to 20%, 5 to 15%), the disclosed insulating compound (e.g., 3 to 20%, 3 to 10%), defoamer (e.g., 0.2 to 3%, 0.2 to 2%), and water (e.g., 10 to 50%, 10 to 30%). In one example, the insulative coating may include a combination of 45 to 60% resin, 5 to 15% micro silica, 2 to 5% inorganic fibers, 3 to 10% disclosed insulating compound, 0.2 to 2% defoamer, and 10 to 30% water. In some aspects, the above examples of the insulative coating may further include one or more of: inorganic fibers (e.g., greater than 0% and less than or equal to 5%, greater than 0% and less than or equal to 10%), a thickener (e.g., greater than 0% and less than or equal to 2%), a dispersant (e.g., greater than 0% and less than or equal to 3%), inert pigments (e.g., greater than 0% and less than or equal to 10%), and semiconductors (e.g., greater than 0% and less than or equal to 6%). Each of the example percentages is by mass.

In various embodiments, the insulating compound included in the insulative coating may be the first, second, third, fourth, fifth, sixth, seventh, eighth, ninth, or tenth example insulating compound provided above. In other embodiments, the insulating compound included in the insulative coating may have another suitable composition consistent with the above description of the insulating compound.

The resin may be a polymer resin and/or may be water-based. The resin enables film formation. For instance, the resin improves binding and keeps all solids in suspension such as pigments, insulation additives, and inert pigments. The resin is also responsible for binding the insulative coating to a substrate. Example resins include acrylic, alchemical, epoxy, polyurethane resins, phenol-formaldehyde, polyurethane, furfural resin, poly acrylonitrile, polyimide, sucrose and tannin.

The micro silica (e.g., micro silica spheres) reduces the insulative coating's density as well as increase the insulative coating's solar reflectance.

The inorganic fibers provide mechanical reinforcement for support of an insulative coating film. In one example, the inorganic fibers are micron-sized amorphous vitreous fibers. Example inorganic fibers include glass, aramid, carbon, and mixed carbon and aramid. In some aspects the inorganic fibers may be functionalized and doped with graphene and nanotubes.

The defoamer prevents a water-based resin from foaming when the water-based resin is agitated at high rotations during manufacturing of the insulative coating. An example defoamer includes water-based polyoxyalkylene mineral oil, modified silica, and water at suitable ratios.

If a thickener is included, the thickener is directly responsible for the insulative coating's viscosity control. It helps in keeping heavy solids from dropping from solution. It also helps in forming a film during deposition, preventing the insulative coating from running from the substrate. An example thickener includes acrylic polymer, residual monomers, and water at suitable ratios.

If a dispersant is included, the dispersant is used to prevent agglomeration and posterior flocculation of the primary solid contents such as in the case of pigments and other additives. Its addition allows the particles to be separated from one another for a long period of time, which helps in even distribution of particles during film formation. An example dispersant includes polycarboxylate (sodium salt), residual monomers, and water at suitable ratios.

If inert pigments are included, the inert pigments are an insoluble solid substance of low granularity that is used principally to give the insulative coating its color. The inert pigments help with light absorption and direction that aid in solar reflectance. Example inert pigments include ferric oxides (e.g., greens, reds, yellows, carbon oxide, chromate 3 or 6 (different colors), calcium carbonate (white), etc.).

If semiconductors are included, the semiconductors are an insoluble solid substance of low granularity used to modify the optical characteristics of the insulative coating. The semiconductors reduce the absorption of, and therefore increase reflection of, light waves in the 380 to 1200 nm range when the insulative coating film dries. The semiconductors may be inorganic semiconductors. Example semiconductors include titanium oxide, magnesium oxide, chromite, aluminum-cobalt (CoAl), iron-chromium (FeCr), nickel-antimony-titanium (Ni—Sb—Ti), and suitable carbides.

### Fireproofing Embodiment

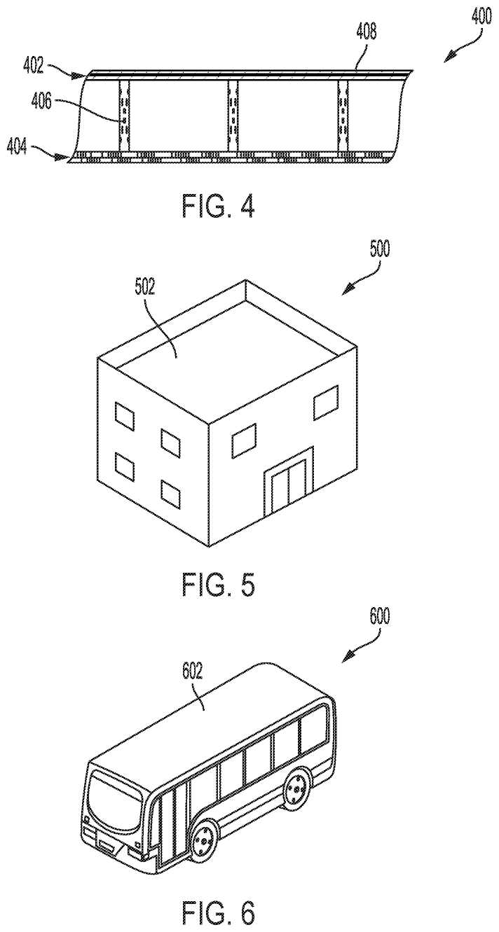

A second example application of the insulating compound is in a fireproof coating. The fireproof coating with an embodiment of the insulating compound exhibits high heat insulation combined with a low flame spread and low smoke density. Such a coating can be applied to any suitable structure for which fireproofing is beneficial. For example, the fireproof coating may be applied to a wide variety of firewalls in place of other typical fireproofing material. FIG. 4 illustrates a schematic of an example structure 400 having at least one layer of floor material 402 (e.g., wood) and at least one layer of ceiling material 404 (e.g., gypsum wallboard or drywall) joined by a plurality of joists 406 (e.g., wood joists). In this example, the at least one layer of ceiling material 404 acts as a firewall and the fire exposed side of the at least one layer of ceiling material 404 may be coated with a fireproof coating 408. The fireproof coating 408 may be any embodiment of the fireproof coating provided herein. In another example, the fireproof coating may be applied to coat tanks of water in order to help prevent a wildfire from burning a water system. In another example, the fireproof coating may coat pipes to protect against fires occurring as a result of military combat. An advantage of the fireproof coating is low weight and high flexibility compared to conventional fireproofing technologies while still providing equivalent or better fireproofing properties. For example, a special type of drywall is typically used for a firewall and multiple layers of this special drywall are often needed, which adds weight, construction time, and material. Conversely, in some instances, one special drywall layer coated with the provided fireproof coating can be used in place of multiple drywall layers. Embodiments of the fireproof coating pass the standard ASTM E119 fire performance test, and have a flame spread index and smoke developed index of 0.

The provided fireproof coating has a low thermal conductivity (e.g., within a range of 0.017 to 0.10 W/mK) and high emissivity, each of which provide the coating with desirable fireproofing properties. For instance, an embodiment of the fireproof coating may have an emissivity of 1.0. In various aspects, the fireproof coating may have an emissivity within a range of 0.95 to 1.0. In at least some aspects, the fireproof coating may operate (e.g., demonstrates a thermal insulation effect) within a temperature range of −32 to 1800° C. (−25 to 3272° F.). For example, the fireproof coating may have a thermal conductivity within a range of 0.017 to 0.10 W/mK when the fireproof coating is exposed to a temperature within a range of −32 to 1800° C. (−25 to 3272° F.). In various embodiments, the fireproof coating can provide the fireproof coating's fireproofing properties when applied, to a surface, with a thickness within a range of 1 to 20 millimeters (mm). For example, the fireproof coating may have a thermal conductivity within a range of 0.017 to 0.10 W/mK when the fireproof coating is applied, to a surface, with a thickness within a range of 1 to 20 millimeters (mm).

In various examples, the fireproof coating includes a combination of: a resin (e.g., 10 to 40%, 20 to 40%), micro silica (e.g., 2 to 15%, 2 to 10%), inorganic fibers (e.g., 3 to 20%, 3 to 10%), the disclosed insulating compound (e.g., 5 to 30%, 10 to 20%), insulative particles (e.g., 3 to 20%, 7 to 20%), inert pigments (e.g., 1 to 10%, 1 to 8%), and water (e.g., 10 to 50%, 15 to 30%). In one example, the fireproof coating includes a combination of 20 to 40% resin, 2 to 10% micro silica, 3 to 10% inorganic fibers, 10 to 20% disclosed insulating compound, 7 to 20% insulative particles, 1 to 8% inert pigments, and 15 to 30% water. In some aspects, the above examples of the fireproof coating may further include one or more of: a thickener (e.g., greater than 0% and less than or equal to 3%, 0 and less than or equal to 2%), a phosphate additive (e.g., greater than 0% and less than or equal to 15%, greater than 0% and less than or equal to 5%), and alumina (e.g., greater than 0% and less than or equal to 15%). Each of the example percentages is by mass.

In various embodiments, the insulating compound included in the fireproof coating may be the first, second, third, fourth, fifth, sixth, seventh, eighth, ninth, or tenth example insulating compound provided above. In other embodiments, the insulating compound included in the fireproof coating may have another suitable composition consistent with the above description of the insulating compound.

The resin may be a polymer resin and/or may be water-based. The resin enables film formation. For instance, the resin binds and keeps all solids in suspension such as pigments, insulation additives, and inert pigments. The resin is also responsible for binding the fireproof coating to a substrate. Example resins include acrylic, alchemical, epoxy, polyurethane resins, phenol-formaldehyde, polyurethane, furfural resin, poly acrylonitrile, polyimide, sucrose and tannin.

The micro silica (e.g., micro silica spheres) reduces the fireproof coating's density as well as increase the fireproof coating's solar reflectance.

The inorganic fibers provide mechanical reinforcement for support of a fireproof coating film. In one example, the inorganic fibers are micron-sized amorphous vitreous fibers. Example inorganic fibers include glass, aramid, carbon, and mixed carbon and aramid. In some aspects the inorganic fibers may be functionalized and doped with graphene and nanotubes.

In at least some aspects, the insulative particles may be nanoparticles. The nanoparticles have a high surface area with a low thermal conductivity, which forms stable dispersions in aqueous solutions. The nanoparticles are also highly reactive given the large surface area per mass of the nanoparticles. In various examples, the nanoparticles have a diameter within a range of 10 nm to 1000 nm, or in some instances within a range of 10 nm to 12 nm. The nanoparticles may be inorganic material that have high heat resistance, good mechanical resistance, and low electrical and thermal conductivity.

The inert pigments are an insoluble solid substance of low granularity that is used principally to give the fireproof coating its color. The inert pigments help with light absorption and direction that aid in solar reflectance. Example inert pigments include ferric oxides (e.g., greens, reds, yellows, carbon oxide, chromate 3 or 6 (different colors), calcium carbonate (white), etc.).

If a thickener is included, the thickener is directly responsible for the fireproof coating's viscosity control. The thickener keeps heavy solids from dropping from solution. It also helps in forming a film during deposition, preventing the fireproof coating from running from the substrate. An example thickener includes acrylic polymer, residual monomers, and water at suitable ratios.

If a phosphate additive is included, the phosphate additive is an inorganic compound used as a thickening agent and to aid in anti-flame spread properties of the fireproof coating.

If alumina is included, the alumina is an additive used to improve the fireproof coating's mechanical properties, particularly against abrasion. For instance, the alumina additive helps aid in avoiding corrosion on substrate metals.

### Roofing Embodiment

Another example application of the insulating compound is in a roof coating. The roof coating can be applied to any suitable roof of any building, such as metal roofs, cement roofs, etc. For example, FIG. 5 illustrates an example commercial building 500 having a roof coating 502 applied to the roof of the commercial building 500. The roof coating 502 may be any of the embodiments of the roof coating described herein. When applied to a roof, the roof coating insulates the building's interior from some of the sun's thermal energy, which would otherwise radiate into the building and raise the interior temperature. The roof coating can therefore reduce energy consumption involved in cooling the building's interior. For instance, the inventors demonstrated that a portion of a roof coated with the provided roof coating showed a 70° F. lower temperature than a non-coated portion of the roof. In at least some aspects, the roof coating may operate (e.g., demonstrates a thermal insulation effect) within a temperature range of −32 to 150° C. (−25 to 302° F.). For example, the roof coating may have a thermal conductivity within a range of 0.05 to 0.25 W/mK when the roof coating is exposed to a temperature within a range of −32 to 150° C. (−25 to 302° F.).

The provided roof coating demonstrates high reflectance, high emissivity, low thermal conductivity, low flame spread, high solar reflectance index (SRI), and acts as a sealer and waterproofer, which all contribute to its desirable properties for use as a thermally insulating roof coating. For instance, an embodiment of the roof coating may have an emissivity of 1.0. In various aspects, the roof coating may have an emissivity within a range of 0.8 to 1.0, and in some instances, within a range of 0.95 to 1.0. The roof coating may have a reflectance (in accordance with the ASTM C1549 standard) within a range of 0.8 to 0.95, and in some aspects, within a range of 0.85 to 0.95. The roof coating may have an emittance (in accordance with the ASTM C1371 standard) within a range of 0.8 to 0.95, and in some aspects, within a range of 0.85 to 0.9. The roof coating may have an SRI within a range of 100 to 125, and in some aspects, within a range of 105 to 120. In various embodiments, the roof coating can provide the roof coating's thermally insulative properties when applied, to a surface, with a thickness within a range of 20 to 60 mils (0.5 to 1.5 mm) when wet, and in some instances, within a range of 40 to 60 mils (1 to 1.5 mm) when wet. For example, the roof coating may have a thermal conductivity within a range of 0.05 to 0.25 W/mK when the roof coating is applied, to a surface, with a thickness within a range of 20 to 60 mils (0.5 to 1.5 mm) when wet, and in some instances, within a range of 40 to 60 mils (1 to 1.5 mm) when wet. In one embodiment, the roof coating is applied with a thickness of 50 mils (1.27 mm) when wet. The thickness of the applied wet roof coating shrinks about 15% when cured.

In various examples, the roof coating includes a combination of: a resin (e.g., 15 to 50%, 20 to 40%), inert pigments (e.g., 5 to 30%, 5 to 20%), semiconductors (e.g., 2 to 20%, 2 to 10%), carbonate (e.g., 10 to 50%, 10 to 25%), alumina (e.g., 5 to 20%, 8 to 18%), the disclosed insulating compound (e.g., 1 to 10%), and water (e.g., 10 to 40%, 10 to 25%). In one example, the roof coating includes 20 to 40% resin, 5 to 20% inert pigments, 2 to 10% semiconductors, 10 to 25% carbonate, 8 to 18% alumina, 1 to 10% disclosed insulating compound, and 10 to 25% water. In some aspects, the above examples of the roof coating may further include one or more of: a thickener (e.g., greater than 0% and less than or equal to 3%, greater than 0% and less than or equal to 2%), a defoamer (e.g., greater than 0% and less than or equal to 2%), and a dispersant (e.g., greater than 0% and less than or equal to 3%, greater than 0% and less than or equal to 1%). Each of the example percentages is by mass.

In various embodiments, the insulating compound included in the roof coating may be the first, second, third, fourth, fifth, sixth, seventh, eighth, ninth, or tenth example insulating compound provided above. In other embodiments, the insulating compound included in the roof coating may have another suitable composition consistent with the above description of the insulating compound.

The resin may be a polymer resin and/or may be water-based. The resin enables film formation. For instance, the resin binds and keeps all solids in suspension such as pigments, insulation additives, and inert pigments. The resin is also responsible for binding the roof coating to a substrate. Example resins include acrylic, alchemical, epoxy, silicone, polyurethane resins, phenol-formaldehyde, polyurethane, furfural resin, poly acrylonitrile, polyimide, sucrose and tannin.

The inert pigments are an insoluble solid substance of low granularity that is used principally to give the roof coating its color. The inert pigments help with light absorption and direction that aid in solar reflectance. Example inert pigments include ferric oxides (e.g., greens, reds, yellows, carbon oxide, chromate 3 or 6 (different colors), calcium carbonate (white), etc.).

The semiconductors are an insoluble solid substance of low granularity used to modify the optical characteristics of the roof coating. The semiconductors reduce the absorption of, and therefore increase reflection of, light waves in the 380 to 1200 nm range when the roof coating film dries. The semiconductors may be inorganic semiconductors. Example semiconductors include titanium oxide, magnesium oxide, chromite, aluminum-cobalt (CoAl), iron-chromium (FeCr), nickel-antimony-titanium (Ni—Sb—Ti), and carbides.

The carbonate is a mineral additive with low granularity that helps the mechanical properties of the dry film roof coating once formed. The carbonate also helps in dispersing all solid additives during blending. Additionally, the carbonate provides some reflective properties to the roof coating.

The alumina is an additive used to improve the roof coating's mechanical properties, particularly against abrasion. For instance, the alumina additive aids in avoiding corrosion on substrate metals.

If a thickener is included, the thickener is directly responsible for the roof coating's viscosity control. The thickener keeps heavy solids from dropping from solution. The thickener also helps in forming a film during deposition, preventing the roof coating from running from the substrate. An example thickener includes acrylic polymer, residual monomers, and water at suitable ratios.

If a defoamer is included, the defoamer prevents a water-based resin from foaming when the water-based resin is agitated at high rotations during manufacturing of the roof coating. An example defoamer includes water-based polyoxyalkylene mineral oil, modified silica, and water at suitable ratios.

If a dispersant is included, the dispersant is used to prevent agglomeration and posterior flocculation of the primary solid contents such as in the case of pigments and other additives. The dispersant's addition allows the particles to be separated from one another for a long period of time, which helps in even distribution of particles during film formation. An example dispersant includes polycarboxylate (sodium salt), residual monomers, and water at suitable ratios.

### Vehicle Coating Embodiment

An additional example application of the insulating compound is in a vehicle coating. For example, the vehicle coating may be applied to the exterior (e.g., roof) of any suitable moving vehicle, such as a bus, RV, delivery truck, construction vehicle (e.g., cement mixer), train car. FIG. 6 illustrates an example bus 600 having a vehicle coating 602 applied to the roof of the bus 600. The vehicle coating 602 may be any embodiment of the vehicle coating described herein. When applied to a vehicle's exterior, the vehicle coating provides the benefit of insulating the vehicle's interior from some of the sun's thermal energy, which would otherwise radiate into the vehicle and increase the interior temperature. An advantage of the vehicle coating is therefore reduced energy consumption involved in cooling the vehicle's interior. Viewing the benefit of the vehicle coating from a different perspective, the vehicle coating can slow the rate at which the temperature of the contents of a vehicle increases, which can be important when the vehicle does not include a cooling system for the contents. For example, coating a cement truck's drum with the vehicle coating can help extend the curing time of the cement in the drum from a plant to a construction site. In at least some aspects, the vehicle coating may operate (e.g., demonstrates a thermal insulation effect) within a temperature range of −32 to 150° C. (−25 to 302° F.). For example, the vehicle coating may have a thermal conductivity within a range of 0.05 to 0.15 W/mK when the vehicle coating is exposed to a temperature within a range of −32 to 150° C. (−25 to 302° F.).

The provided vehicle coating demonstrates high reflectance, high emissivity, low thermal conductivity, and high solar reflectance index (SRI), and is suitable for high vibration high uplift winds, which all contribute to its desirable properties for use as a thermally insulating vehicle coating. For instance, an embodiment of the vehicle coating may have an emissivity of 1.0. In various aspects, the vehicle coating may have an emissivity within a range of 0.95 to 1.0. The vehicle coating may have a reflectance (in accordance with the ASTM C1549 standard) within a range of 0.8 to 0.95, and in some aspects, within a range of 0.85 to 0.95. The vehicle coating may have an emittance (in accordance with the ASTM C1371 standard) within a range of 0.8 to 0.9, and in some aspects, within a range of 0.85 to 0.9. The vehicle coating may have an SRI within a range of 100 to 120, and in some aspects, within a range of 105 to 120. In various embodiments, the vehicle coating can provide the vehicle coating's insulative properties when applied, to a surface, with a thickness within a range of 40 to 60 mils (1 to 1.5 mm) when wet. For example, the vehicle coating may have a thermal conductivity within a range of 0.05 to 0.15 W/mK when the vehicle coating is applied, to a surface, with a thickness within a range of 40 to 60 mils (1 to 1.5 mm) when wet. In one embodiment, the vehicle coating is applied with a thickness of 50 mils (1.27 mm) when wet. The thickness of the applied wet vehicle coating shrinks about 15% when cured.

In various examples, the vehicle coating includes a combinations of: a resin (e.g., 15 to 50%, 20 to 40%), inert pigments (e.g., 5 to 30%, 5 to 20%), semiconductors (e.g., 2 to 15%, 2 to 10%), carbonate (e.g., 5 to 40%, 5 to 20%), the disclosed insulating compound (e.g., 1 to 20%, 4 to 18%), and water (e.g., 10 to 50%, 10 to 30%). In one example, the vehicle coating includes 20 to 40% resin, 5 to 20% inert pigments, 1 to 10% semiconductors, 5 to 20% carbonate, 4 to 18% disclosed insulating compound, and 10 to 30% water. In some aspects, the above examples of the vehicle coating may further include one or more of: micro silica (e.g., greater than 0% and less than or equal to 10%), a thickener (e.g., greater than 0% and less than or equal to 1%), a defoamer (e.g., greater than 0% and less than or equal to 2%), and a dispersant (e.g., greater than 0% and less than or equal to 4%). Each of the example percentages is by mass.

In various embodiments, the insulating compound included in the vehicle coating may be the first, second, third, fourth, fifth, sixth, seventh, eighth, ninth, or tenth example insulating compound provided above. In other embodiments, the insulating compound included in the vehicle coating may have another suitable composition consistent with the above description of the insulating compound.

The resin may be a polymer resin and/or may be water-based. The resin enables film formation. For instance, the resin binds and keeps all solids in suspension such as pigments, insulation additives, and inert pigments. The resin is also responsible for binding the vehicle coating to a substrate. Example resins include acrylic, alchemical, silicone, epoxy, polyurethane resins, phenol-formaldehyde, polyurethane, furfural resin, poly acrylonitrile, polyimide, sucrose and tannin.

The inert pigments are an insoluble solid substance of low granularity that is used principally to give the vehicle coating its color. The inert pigments help with light absorption and direction that aid in solar reflectance. Example inert pigments include ferric oxides (e.g., greens, reds, yellows, carbon oxide, chromate 3 or 6 (different colors), calcium carbonate (white), etc.).

The semiconductors are an insoluble solid substance of low granularity used to modify the optical characteristics of the vehicle coating. The semiconductors reduce the absorption of, and therefore increase reflection of, light waves in the 380 to 1200 nm range when the vehicle coating film dries. The semiconductors may be inorganic semiconductors. Example semiconductors include titanium oxide, magnesium oxide, chromite, aluminum-cobalt (CoAl), iron-chromium (FeCr), nickel-antimony-titanium (Ni—Sb—Ti), and carbides.

The carbonate is a mineral additive with low granularity that helps the mechanical properties of the dry film vehicle coating once formed. The carbonate also helps in dispersing all solid additives during blending. Additionally, the carbonate provides some reflective properties to the vehicle coating.

If included, the micro silica (e.g., micro silica spheres) helps reduce the vehicle coating's density as well as increase the vehicle coating's solar reflectance.

If a thickener is included, the thickener is directly responsible for the vehicle coating's viscosity control. It helps in keeping heavy solids from dropping from solution. It also helps in forming a film during deposition, preventing the vehicle coating from running from the substrate. An example thickener includes acrylic polymer, residual monomers, and water at suitable ratios.

If a defoamer is included, the defoamer prevents a water-based resin from foaming when the water-based resin is agitated at high rotations during manufacturing of the vehicle coating. An example defoamer includes water-based polyoxyalkylene mineral oil, modified silica, and water at suitable ratios.

If a dispersant is included, the dispersant is used to prevent agglomeration and posterior flocculation of the primary solid contents such as in the case of pigments and other additives. The dispersant's addition allows the particles to be separated from one another for a long period of time, which helps in even distribution of particles during film formation.

### Solar Panel Embodiment

Another example application of the insulating compound is in a solar panel coating. Solar panels lose their efficiency when they get too hot. An advantage of the provided solar panel coating is that the solar panel coating allows enough light to pass through and reach the solar cells while also reducing heat transfer to the solar panel, thereby slowing the rate at which the solar panel heats up. For instance, the solar panel coating allows over 90% transmission for light in the 380 to 850 nm wavelength range. Additionally, in an unexpected result, the inventors demonstrated that a silicon monoxide substrate coated with the solar panel coating had greater light transmission than the silicon monoxide substrate without the coating. The solar panel coating reduces heat transfer and promotes cooling of the solar panel at least in part by increasing emissivity of the solar panel's surface. For instance, the inventors demonstrated that an embodiment of the solar panel coating may have an emissivity of 0.86. In various aspects, the solar panel coating may have an emissivity within a range of 0.80 to 0.86. The solar panel coating therefore elevates the solar panel's performance. For instance, the inventors demonstrated that the solar panel coating increased a solar panel's efficiency by 68%. In various embodiments, the solar panel coating can provide the solar panel coating's advantageous insulative properties when applied, to the exposed layer of the solar panel, with a thickness within a range of 80 to 100 microns (mm). For example, the solar panel coating may have a thermal conductivity of 0.05 W/mK at 5% loading when applied, to the exposed layer of the solar panel, with a thickness within a range of 80 to 100 microns (mm).

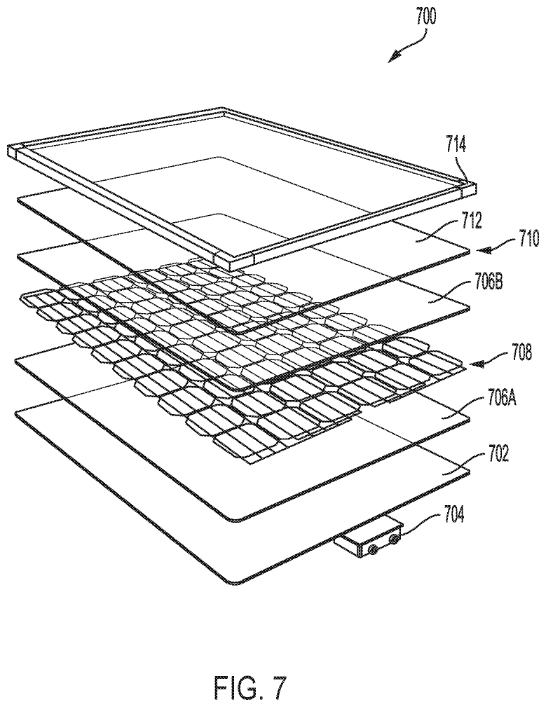

FIG. 7 illustrates an exploded view of an example solar panel 700. The solar panel 700 includes a back sheet 702 attached to a junction box 704. A plurality of solar cells 708 are encapsulated between layers of encapsulant 706A and 706B (e.g., ethylene vinyl acetate (EVA)). Each of the solar cells of the plurality of solar cells 708 may be any suitable photoelectric device that converts incident light energy to electric energy. For example, the plurality of solar cells 708 may include crystalline silicon solar cells, such as monocrystalline silicon solar cells or polycrystalline solar cells. In other examples, the plurality of solar cells 708 may include thin-film solar cells, such as cadmium telluride solar cells, copy indium gallium selenide solar cells, or amorphous silicon solar cells. In other examples still, the plurality of solar cells 708 may include dye-sensitized solar cells, organic solar cells, copper zinc tin sulfide (CZTS) solar cells, perovskite solar cells, or quantum dot solar cells. The plurality of solar cells 708 may be rigid or flexible. A transparent layer 710 (e.g., glass) is disposed on the encapsulant layer 706B. The transparent layer 710 is the outermost, exposed layer of the solar panel 700. In this example, the transparent layer 710 is coated with a solar panel coating 712 on the exposed side of the transparent layer 710. A frame 714 (e.g., aluminum) secures all of the components of the solar panel 700 together between the frame 714 and the back sheet 702. While in this example the solar panel coating 712 is applied to the exposed side of the transparent layer 710 of the solar panel 700, in other examples the solar panel coating 712 may be integrated with the transparent layer 710 itself.

The solar panel coating may include a resin and the disclosed insulating compound. The insulating compound may be 1 to 10% (e.g., 1 to 5%) of the solar panel coating by mass and a resin constitutes the remaining portion of the solar panel coating by mass. In some examples, the solar panel may further include up to 10% additives by mass. The resin is a carrier responsible for film formation with its main function being to bind to a substrate of a solar panel (e.g., glass or other suitable protective coating for a solar panel) with as minimal light obstruction as possible. The resin may be clear (e.g., transparent) at least in wavelengths corresponding to light wavelengths intended for capture by photovoltaic conversion in the solar cell. In some embodiments, the resin may be a polymer. Example resins include silicone, urethane, or other suitable carriers that are highly transparent such as acrylic or polyethylene terephthalate (PET). In various aspects of the solar panel coating, the insulating compound may have an average granularity of five micron or less.

In various embodiments, the insulating compound included in the solar panel coating may be the first, second, third, fourth, fifth, sixth, seventh, eighth, ninth, or tenth example insulating compound provided above. In other embodiments, the insulating compound included in the solar panel coating may have another suitable composition consistent with the above description of the insulating compound.

### Ceramic Embodiment

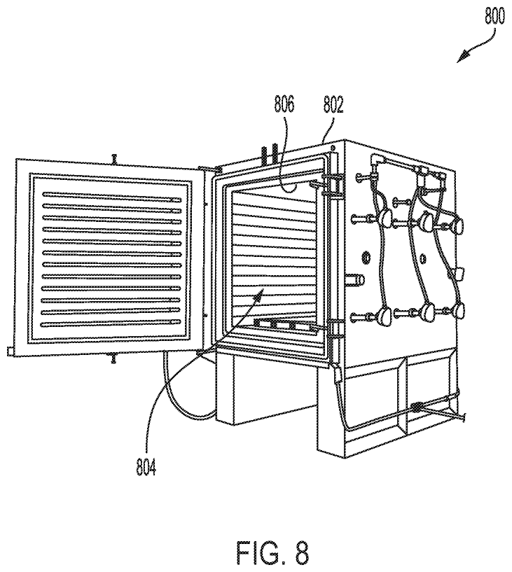

An additional example application of the insulating compound is in a hard ceramic coating having refractory properties. The ceramic coating may be used as a replacement for refractory materials. As opposed to polymer-based coatings that are sacrificial when exposed to extreme temperatures, the ceramic coating is a non-sacrificial, fully inorganic (e.g., free of organic components) coating that resists many thermal cycles. As such, an advantage of the ceramic coating is that the ceramic coating may be used in situations where a burning off of organic components would cause contamination. The ceramic coating is also thinner and lighter than conventional refractory materials the ceramic coating can replace. In an example usage scenario, the outer casing of a furnace typically absorbs a significant amount of heat that could otherwise be used to heat the furnace's contents, and in some instances, could damage (e.g., melt) the furnace's outer casing. FIG. 8 illustrates an example furnace 800 having a structure 802 that defines an interior 804 of the structure 802. Contents to be heated by the furnace 800 can be placed in the interior 804 of the structure 802. At least a portion of the surface of the structure 802 that is exposed to the interior 804 may be coated with a ceramic coating 806. In some aspects, the ceramic coating 806 may be applied to a surface of the structure 802 facing the exterior of the furnace 800. The ceramic coating 806 may be any embodiment of the provided ceramic coating. Applying an embodiment of the provided ceramic coating to the interior of the furnace's outer casing (e.g., structure 802) reduces the outer casing's thermal absorption thereby enabling more of the furnace's generated heat to be used for its intended purpose-heating the furnace contents. The ceramic coating may also protect the furnace's outer casing from damage.

The ceramic coating demonstrates high emissivity, low thermal conductivity, and high resistance mechanical properties, which are all desirable properties for use as a thermally insulating replacement coating for refractory materials. In at least some aspects, the ceramic coating may operate (e.g., demonstrates a thermal insulation effect) within a temperature range of −150 to 1800° C. (−238 to 3272° F.). For example, the ceramic coating may have a thermal conductivity within a range of 0.035 to 0.10 W/mK when exposed to a temperature within a range of −150 to 1800° C. (−238 to 3272° F.). Embodiments of the ceramic coating pass the standard ASTM E119 fire performance test. In various embodiments, the ceramic coating can provide the ceramic coating's thermally insulative properties when applied, to a surface, with a thickness within a range of 1 to 20 mm when dry. For example, the ceramic coating may have a thermal conductivity within a range of 0.035 to 0.10 W/mK when applied, to a surface, with a thickness within a range of 1 to 20 mm when dry. In some embodiments, the ceramic coating is applied with a thickness within a range of 3 to 7 mm when dry.

In various examples, the ceramic coating includes a combinations of: insulative particles (e.g., 15 to 37%, 15 to 30%), amorphous silica (e.g., 25 to 50%, 30 to 45%), inorganic fibers (e.g., 5 to 20%, 8 to 18%), the disclosed insulating compound (e.g., 5 to 20%), and water (e.g., 5 to 17%). In one example, the ceramic coating includes 15 to 30% insulative particles, 30 to 45% amorphous silica, 8 to 18% inorganic fibers, 5 to 20% disclosed insulating compound, and 5 to 17% water. In some aspects, the above examples of the ceramic coating may further include bentonite (e.g., greater than 0% and less than or equal to 3%). Each of the example percentages is by mass.

In various embodiments, the insulating compound included in the ceramic coating may be the first, second, third, fourth, fifth, sixth, seventh, eighth, ninth, or tenth example insulating compound provided above. In other embodiments, the insulating compound included in the ceramic coating may have another suitable composition consistent with the above description of the insulating compound.

In at least some aspects, the insulative particles may be nanoparticles. The nanoparticles have a high surface area with a low thermal conductivity, which forms stable dispersions in aqueous solutions. The nanoparticles are also highly reactive given the large surface area per mass of the nanoparticles. In various examples, the nanoparticles have a diameter within a range of 10 nm to 1000 nm, or in some instances within a range of 10 nm to 12 nm. The nanoparticles may be inorganic material that have high heat resistance, good mechanical resistance, and low electrical and thermal conductivity.

The amorphous silica is an additive with low thermal expansion and low thermal conductivity that forms a new ceramic phase having refractory characteristics via a chemical reaction with the disclosed insulating compound.

The inorganic fibers provide mechanical reinforcement for support of a ceramic coating film. The inorganic fibers may aid in the sintering process during impingent flame or heat flux. In one example, the inorganic fibers are micron-sized amorphous vitreous fibers. Example inorganic fibers include glass, aramid, carbon, and mixed carbon and aramid. In some aspects the inorganic fibers may be functionalized and doped with graphene and nanotubes.

If included, the bentonite is used as an inorganic thickening agent. Bentonite's main function is to increase viscosity in the ceramic coating.

### CONCLUSION

As described above, each of the disclosed embodiments provides thermal insulation advantages for each of their respective example uses. These thermal insulation advantages are due, at least in part, to the insulating compound conceived by the inventors. It will be appreciated that each of the example uses provided for the above embodiments are merely exemplary and not intended to be limiting. Features, advantages, and uses other than those described for each embodiment will be apparent to one of ordinary skill in the art based on the above Description.

As used herein, “about,” “approximately” and “substantially” are understood to refer to numbers in a range of numerals, for example the range of −10% to +10% of the referenced number, preferably −5% to +5% of the referenced number, more preferably −1% to +1% of the referenced number, most preferably −0.1% to +0.1% of the referenced number.

Furthermore, all numerical ranges herein should be understood to include all integers, whole or fractions, within the range. Moreover, these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth. Additionally, a disclosure of a range from 1 to 10 includes 1 and 10 in that range.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

1. A solar panel comprising:
at least one solar cell;
a transparent layer disposed between the at least one solar cell and the ambient environment of the solar panel; and
a composition of matter applied to the transparent layer, wherein the composition of matter includes, by mass:
1 to 10% insulating compound; and
a remaining portion resin,
wherein the insulating compound includes:
2 to 60% insulative particles,
5 to 40% micro silica, and
15 to 50% amorphous silica.

2. The solar panel of claim 1, wherein the resin is one in the group consisting of:
silicone, urethane, acrylic, and polyethylene terephthalate (PET).

3. The solar panel of claim 1, wherein the composition of matter further includes, by mass, greater than 0% and less than or equal to 10% additives.

4. The solar panel of claim 1, wherein the composition of matter has an emissivity within a range of 0.80 to 0.86.

5. The solar panel of claim 1, wherein the composition of matter allows transmission of light through the composition of matter in the 380 to 850 nm wavelength range.

6. The solar panel of claim 1, wherein the composition of matter has a thickness within a range of 80 to 100 microns.

7. The composition of matter of claim 1, wherein the insulating compound further includes one or more in the group consisting of: electro-fused silica, hydrated silica, inorganic fibers, bentonite, semiconductors, inert pigments, carbides, additives, resin, and water.

8. The composition of matter of claim 7, wherein the insulating compound includes, by mass, 5 to 50% electro-fused silica.

9. The composition of matter of claim 7, wherein the insulating compound includes, by mass, 20 to 40% hydrated silicate.

10. The composition of matter of claim 7, wherein the insulating compound includes, by mass, 5 to 40% fibers.

11. The composition of matter of claim 7, wherein the insulating compound includes, by mass, 1 to 5% bentonite.

12. The composition of matter of claim 7, wherein the insulating compound includes, by mass, 5 to 50% semiconductors.

13. The composition of matter of claim 1, wherein the insulating compound includes, by mass:
10 to 30% insulative particles,
5 to 10% micro silica,
25 to 50% amorphous silica, and
20 to 40% water.

14. A solar panel comprising:
at least one solar cell;
a transparent layer disposed between the at least one solar cell and the ambient environment of the solar panel; and
a composition of matter integrated with the transparent layer, wherein the composition of matter includes, by mass:
1 to 10% insulating compound; and
a remaining portion resin,
wherein the insulating compound includes:
2 to 60% insulative particles,
5 to 40% micro silica, and
15 to 50% amorphous silica.

15. The composition of matter of claim 14, wherein the insulating compound further includes, by mass, 1 to 10% inert pigments.

16. The composition of matter of claim 14, wherein the insulating compound further includes, by mass, 5 to 35% carbides.

17. The composition of matter of claim 14, wherein the insulating compound further includes, by mass, 5 to 60% resin.

18. The composition of matter of claim 14, wherein the insulating compound further includes, by mass, 20 to 60% water.

19. The solar panel of claim 1, wherein the composition of matter has an emissivity within a range of 0.80 to 0.86.

20. The solar panel of claim 1, wherein the composition of matter allows transmission of light through the composition of matter in the 380 to 850 nm wavelength range.
